(19) United States
(12) Patent Application Publication
(10) Pub. No.: US 2024/0210494 A1
(43) Pub. Date: Jun. 27, 2024

(54) MAGNETIC DETECTION DEVICE

(71) Applicant: ROHM CO., LTD., Kyoto (JP)

(72) Inventors: Eiji KUWAHARA, Kyoto (JP); Toru HIGUCHI, Kyoto (JP)

(73) Assignee: ROHM CO., LTD., Kyoto (JP)

(21) Appl. No.: 18/545,805

(22) Filed: Dec. 19, 2023

(30) Foreign Application Priority Data
Dec. 23, 2022 (JP) 2022-206885

(51) Int. Cl. G01R 33/00

(52) U.S. Cl. CPC G01R 33/0011; G01R 33/07

(57) ABSTRACT

The present disclosure provides a magnetic detection device. The magnetic detection device includes: a magnetic detection element; a substrate, having an opposing surface facing the magnetic detection element; and a magnetic collector, disposed between the magnetic detection element and the substrate and configured to induce a magnetic flux to the magnetic detection element. The substrate has a recess recessed from the opposing surface in a direction opposite to the magnetic detection element. At least a portion of the magnetic collector is disposed within the recess. The magnetic collector includes a first magnetic collecting unit that stands up from a bottom surface of the recess toward the magnetic detection element.

### TECHNICAL FIELD

The present disclosure relates to a magnetic detection device.

### BACKGROUND

Patent publication 1 discloses a configuration of a packaged magnetic detection device. The magnetic detection device of patent publication 1 includes a lead frame, a Hall element mounted at the lead frame, and a sealing resin sealing the Hall element.
[Prior art document]
[Patent publication]
[Patent document 1] Japan Patent Publication No. 2014- 077730

### BRIEF DESCRIPTION OF THE DRAWINGS

FIG. 1 is a brief section diagram of a magnetic detection device according to a first embodiment.

FIG. 2 is a perspective diagram of a substrate according to the first embodiment.

FIG. 3 is a perspective diagram of a magnetic collector according to the first embodiment.

FIG. 4 is a brief section diagram of a manufacturing step of a magnetic detection device.

FIG. 5 is a brief section diagram of a manufacturing step of a magnetic detection device.

FIG. 6 is a brief section diagram of a manufacturing step of a magnetic detection device.

FIG. 7 is a brief section diagram of a magnetic detection device according to a second embodiment.

FIG. 8 is a brief section diagram of a magnetic detection device of a variation example.

### DETAILED DESCRIPTION OF THE EMBODIMENTS

Details of the embodiments of the present disclosure are given with the accompanying drawings below.

To keep the description clear and simple, the constituting elements shown in the drawings are not necessarily drawn in constant scales. Moreover, for better understanding, shading lines may be omitted from the section views. It should be noted that the drawings are for illustrating the embodiments of the present disclosure, and are not to be construed as limitations to the present disclosure.

The description below includes details for implementing a device, a system and a method of the exemplary embodiments of the present disclosure. The detailed description is intended for illustration purposes and is not to be construed as limitations to the embodiments of the present disclosure or applications or uses of these embodiments.

### <FIRST EMBODIMENT>

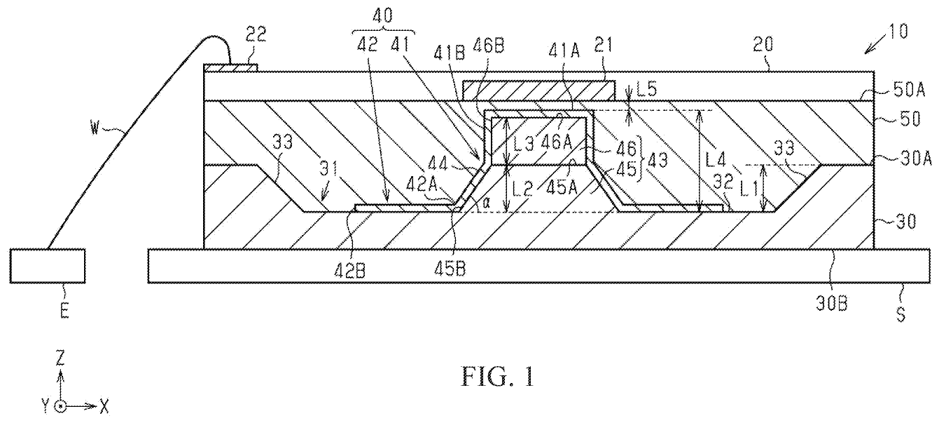

Referring to FIG. 1 to FIG. 3, a magnetic detection device 10 according to the first embodiment is described below.

FIG. 1 shows a brief section diagram of a magnetic detection device 10. Moreover, “X direction” used in the present disclosure refers to an X direction of X, Y and Z axes perpendicular to one another shown in FIG. 1, “Y direction” refers to a Y direction of the X, Y and Z axes, and “Z direction” refers to a Z direction of the X, Y and Z axes. A term such as “in a plan view” used in the present disclosure refers to observing the magnetic detection device 10 from top of the Z axis of the X, Y and Z axes.

The magnetic detection device 10 is formed as a magnetic detection device that is surface-mounted on a circuit substrate S of an electronic device. FIG. 1 shows the magnetic detection device 10 in a state of being surface-mounted on the circuit substrate S. The magnetic detection device 10 includes a magnetic detection element 20, a substrate 30 having an opposing surface 30A facing the magnetic detection element 20, and a magnetic collector 40 disposed between the magnetic detection element 20 and the substrate 30 and configured to induce a magnetic flux to the magnetic detection element 20. Moreover, the magnetic detection device 10 includes an insulating layer 50 disposed between the magnetic detection element 20 and the substrate 30. The magnetic collector 40 is disposed in the insulating layer 50.

### (Magnetic Detection Element)

The magnetic detection element 20 is not specifically defined, and can be implemented by a generally known sensor for detecting a magnetic flux. The magnetic detection element 20 is, for example, a semiconductor layer including P-type silicon, and a Hall element that forms an N-type semiconductor region by introducing an N-type conductive impurity to a surface of the semiconductor layer. Moreover, the magnetic detection element 20 can also be an element other than a Hall element.

The magnetic detection element 20 is disposed on an upper surface 50A of the insulating layer 50, that is, a surface of the insulating layer 50 opposite to the substrate 30. The magnetic detection element 20 includes a sensor unit 21 for detecting a magnetic flux, and an electrode pad 22 which is an external connection terminal. The sensor unit 21 and the electrode pad 22 are electrically connected by a wiring (not shown). The electrode pad 22 is electrically connected to an external electrode E by a conductive wire W. The conductive wire W is a bonding wire formed by a wire bonding device. Each of the electrode pad 22 and the conductive wire W is made of, for example, a conductor such as Au, Al and Cu.

### (Substrate)

The substrate 30 is a component that becomes the basis of the magnetic detection device 10. The substrate 30 includes a semiconductor material which is a monocrystalline material. In one example, the substrate 30 is a Si-containing monocrystalline material.

The substrate 30 has an opposing surface 30A facing the magnetic detection element 20 and a back surface 30B located opposite to the opposing surface 30A, and has a tablet shape with the Z direction as a thickness direction. The opposing surface 30A and the back surface 30B are surfaces parallel to the X direction and the Y direction. A thickness size (a size in the Z direction) of the substrate 30 is, for example, between about 0.1 mm and about 2.0 mm.

In a plan view, the substrate 30 has a rectangular shape having sides extending in the X direction and sides extending in the Y direction, wherein a size in the X direction is greater than a size in the Y direction. Moreover, the shape of the substrate 30 in the plan view is not limited to the rectangular shape above, but can be other shapes such as a square, a polygon or a circle.

The substrate 30 has a recess 31 recessed from the opposing surface 30A in a direction opposite to the magnetic detection element 20, that is, recessed toward a direction of the back surface 30B. The recess 31 has a bottom surface 32, and a side surface 33 connecting the bottom surface 32 of the recess 31 with the opposing surface 30A. A depth of the recess 31, that is, a length L1 from the opposing surface 30A to the bottom surface 32 of the recess 31 is, for example, between about 0.1 μm and about 200 μm.

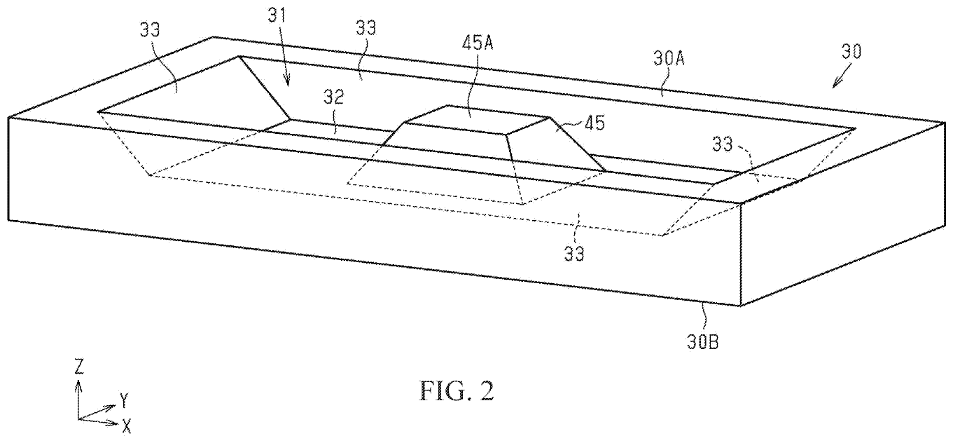

FIG. 2 shows a perspective diagram of the substrate 30 having the recess 31 to represent an example of a shape of the recess 31. An example of the shape of the recess 31 shown in FIG. 2 is specifically described below. The bottom surface 32 of the recess 31 is a surface parallel to the opposing surface 30A. In the plan view, the bottom surface 32 of the recess 31 has a rectangular shape having sides extending in the X direction and sides extending in the Y direction, wherein a size in the X direction is greater than a size in the Y direction. The side surface 33 of the recess 31 consists of four side surfaces facing the X direction or the Y direction. The recess 31 has a square pyramid shape in which a distance of the side surface 33 in the X direction and the Y direction gradually increases from the bottom surface 32 of the recess 31 toward the opposing surface 30A (toward the magnetic detection element 20). Thus, the four sides 33 of the recess 31 are sloped surfaces sloped relative to the opposing surface 30A.

Moreover, the shape of the recess 31 is not limited to a specific shape. For example, the bottom surface 32 of the recess 31 in the plan view can also be other shapes such as a square, a polygon or a circle. In addition, the recess 31 can also have a shape in which a distance of the side surface 33 of the recess 31 is constant from the bottom surface 32 of the recess 31 toward the opposing surface 30A, for example, having a rectangular shape. In this case, all side surfaces forming the side surfaces 33 of the recess 31 become upright surfaces perpendicular to the opposing surface 30A. A sloped angle of the side surface 33 of the recess 31 relative to the opposing surface 30A can be adjusted by means of, for example, a selected etching method used to etch the substrate 30 to form the recess 31. For example, when the substrate 30 is a S-containing monocrystalline material, the side surface 33 becomes a sloped surface if alkali etching is adopted, or the side surface 33 becomes an upright surface if dry etching is adopted.

### (Magnetic Collector).

As shown in FIG. 1, the magnetic collector 40 is located on the bottom surface 32 of the recess 31, with at least a portion thereof disposed within the recess 31. The magnetic collector 40 includes a first magnetic collecting unit 41 that erects from the bottom surface 32 of the recess 31 toward the magnetic detection element 20, and a second magnetic collecting unit 42 that is more protruded laterally than the first magnetic collecting unit 41 in the plan view. The magnetic collector 40 induces a magnetic flux passing through the second magnetic collecting unit 42 to the magnetic detection element 20 via the first magnetic collecting unit 41.

### [First Magnetic Collecting Unit]

The first magnetic collecting unit 41 includes a support portion 43 which is cylindrical and erects from the bottom surface 32 of the recess 31 toward the magnetic detection element 20, and a magnetic film 44 coated on a surface of the support portion 43.

The support portion 43 includes a first support portion 45 formed by a portion of the substrate 30, and a second support portion 46 disposed on the first support portion 45. The first support portion 45 is a portion of the substrate 30, and is a portion that protrudes from the bottom surface 32 of the recess 31 toward the magnetic detection element 20. Thus, the first support portion 45 is made of a same material as the substrate 30. The first support portion 45 is disposed at a center of the bottom surface 32 of the recess 31 in the plan view, and is separated from the side surface 33 of the recess 31.

In the thickness direction of the substrate 30, the first support portion 45 has an upper surface 45A on an end portion of the first support portion 45 located on a side of the magnetic detection element 20, and a side surface 45B connecting the bottom surface 32 of the recess 31 with the upper surface 45A. The first support portion 45 has a pyramid shape having a cross-sectional area gradually decreasing from the bottom surface 32 of the recess 31 toward the upper surface 45A. The first support portion 45 has, for example, a polygonal pyramid shape such as a square pyramid shape. Thus, each side surface 45B of the first support portion 45 becomes a sloped surface sloped relative to the bottom surface 32 of the recess 31. An angle α formed between the bottom surface 32 of the recess 31 and the side surface 45B is, for example, between about 10 degrees and about 90 degrees.

Moreover, the first support portion 45 can also have a cylindrical shape having a constant cross-sectional area from the bottom surface 32 of the recess 31 toward the upper surface 45A. In this case, the first support portion 45 has, for example, a polygonal prism shape such as a square prism shape. Thus, each side surface 45B of the first support portion 45 becomes an upright surface perpendicular to the bottom surface 32 of the recess 31. The sloped angle of the side surface 45B relative to the opposing surface 30A, similar to that of the side surface 33 of the recess 31, can be adjusted by means of, for example, a selected etching method used to etch the substrate 30 to form the first support portion 45. An example where the first support portion 45 is formed to have a square pyramid shape is described below. The first support portion 45 having a polygonal pyramid shape such as a square pyramid shape is a support sloped portion having a cross-sectional area gradually decreasing from the bottom surface 32 of the recess 31 toward the magnetic detection element 20.

In the thickness direction of the substrate 30, a position of the upper surface 45A of an end portion of the first support portion 45 located on a side of the magnetic detection element 20 is equal to a position of the opposing surface 30A of the substrate 30. That is to say, a length L2 of the first support portion 45 in the thickness direction of the substrate 30, that is, a length in the thickness direction of the substrate 30 from the bottom surface 32 of the recess 31 to the upper surface 45A of the first support portion 45, is equal to the depth (the length L1) of the recess 31. Moreover, the position of the upper surface 45A of the first support portion 45 can also be located closer to the bottom surface 32 of the recess 31 than the opposing surface 30A. The length L2 of the first support portion 45 is, for example, between about 0.1 μm and about 200 μm.

The second support portion 46 is made of a material different from the first support portion 45, that is, made of a material different from the substrate 30. The material forming the second support portion 46 is, for example, a non-magnetic material such as Cu. Moreover, the material forming the second support portion 46 can also be a magnetic material.

The second support portion 46 is disposed on the upper surface 45A of the first support portion 45. The second support portion 46 has an upper surface 46A on an end portion of the second support portion 46 located on a side of the magnetic detection element 20, and a side surface 46B connecting the upper surface 45A of the first support portion 45 with the upper surface 46A. The second support portion 46 extends in the thickness direction of the substrate 30 from the upper surface 45A of the first support portion 45, and has a cylindrical shape having a constant cross-sectional from the upper surface 45A of the first support portion 45 toward the magnetic detection element 20. The second support portion 46 has, for example, a polygonal prism shape such as a square prism shape. Thus, each side surface 46B of the second support portion 46 becomes an upright surface perpendicular to the bottom surface 32 of the recess 31. An example where the second support portion 46 is formed to have a square pyramid shape is described below. The second support portion 46 having a polygonal prism shape such as a square prism shape is a support upright portion having a constant cross-sectional area from an upper end of the support sloped portion (the first support portion 45) toward the magnetic detection element 20.

The second support portion 46 is located outside the recess 31 in the thickness direction of the substrate 30. Thus, a portion or an entirety of the second support portion 46 is located outside the recess 31 in the thickness direction of the substrate 30. In other words, a portion or an entirety of the second support portion 46 is located closer to the magnetic detection element 20 than the opposing surface 30A of the substrate 30. A length L3 of the second support portion 46 in the thickness direction of the substrate 30, that is, a length in the thickness direction of the substrate 30 from the upper surface 45A of the first support portion 45 to the upper surface 46A of the second support portion 46 is, for example, between about 0.1 μm and about 200 μm.

In the thickness direction of the substrate 30, a ratio of the length L2 of the first support portion 45 (the support sloped portion) to the length L3 of the second support portion 46 (the support upright portion) is not specifically defined. In one example of the first magnetic collecting unit 41, the length L2 of the first support portion 45 (the support sloped portion) is greater than the length L3 of the second support portion 46 (the support upright portion). Moreover, in one example of the first magnetic collecting unit 41, the length L2 of the first support portion 45 (the support sloped portion) is less than the length L3 of the second support portion 46 (the support upright portion).

The magnetic film 44 is disposed on a surface of the support portion 43, that is, on each side surface 45B of the first support portion 45 (the support sloped portion), and the upper surface 46A and each side surface 46B of the second support portion 46 (the support upright portion). The magnetic film 44 is made of a magnetic material. The magnetic material forming the magnetic film 44 is, for example, ferrite, Fe and Ni. A film thickness of the magnetic film 44 is, for example, between about 0.1 μm and about 50 μm. The film thickness of the magnetic film 44 can be constant or be partially different.

The first magnetic collecting unit 41 has a magnetic collecting opposing surface 41A on an end portion of the first magnetic collecting unit 41 on a side of the magnetic detection element 20 and facing the magnetic detection element 20, and a magnetic collecting side surface 41B extending from an end portion of the first magnetic collecting unit 41 on a side of the substrate 30 toward the magnetic collecting opposing surface 41A. The magnetic collecting opposing surface 41A and the magnetic collecting side surface 41B are surfaces formed by the magnetic film 44. In the thickness direction of the substrate 30, the end portion (the magnetic collecting opposing surface 41A) of the first magnetic collecting unit 41 is located closer to the magnetic detection element 20 than the opposing surface 30A of the substrate 30.

Preferably, a length L4 of the first magnetic collecting unit 41 from the bottom surface 32 of the recess 31 to the magnetic collecting opposing surface 41A, that is, a height size of the first magnetic collecting unit 41, is large. The length L4 of the first magnetic collecting unit 41 is a sum of a protruding height of the support portion 43 and the film thickness of the magnetic film 44. Thus, the length L4 of the first magnetic collecting unit 41 can be adjusted by means of modifying one or both of the protruding height of the support portion 43 and the film thickness of the magnetic film 44. By modifying a height size (a size in the Z direction) of the second support portion 46, the protruding height of the support portion 43 can be easily adjusted. The length L4 of the first magnetic collecting unit 41 is, for example, between about 0.3 μm and about 450 μm.

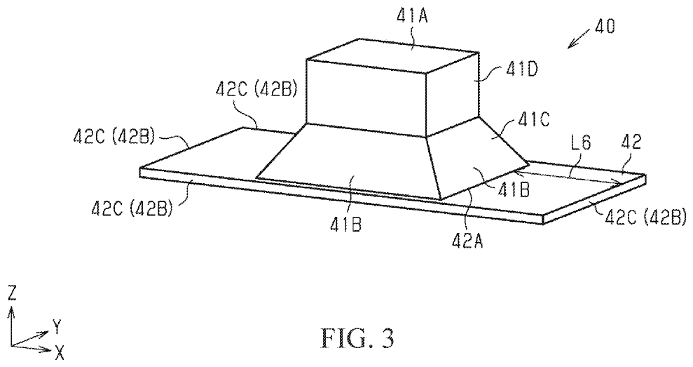

FIG. 3 shows a perspective diagram of the magnetic collector 40 according to the first embodiment to represent an example of the shape of the magnetic collector 40 of the first embodiment. An overall shape of the first magnetic collecting unit 41 shown in FIG. 3 is specifically described below. The first magnetic collecting unit 41 has a shape including a first portion 41C in a square pyramid with the thickness direction of the substrate 30 as a height direction, and a second portion 41D in a rectangular shape with the thickness direction of the substrate 30 as a height direction. An outer periphery of an upper end of the first portion 41C is consistent with an outer periphery of a lower end of the second portion 41D. The first portion 41C is a portion formed by the first support portion 45 (the support sloped portion) and the magnetic film 44 disposed on a surface thereof. The second portion 41D is a portion formed by the second support portion 46 (the support upright portion) and the magnetic film 44 disposed on a surface thereof.

The first magnetic collecting unit 41 has the magnetic collecting opposing surface 41A facing the Z direction, and four magnetic collecting side surfaces 41B facing the X direction or the Y direction in the plan view. Each of the four magnetic collecting side surfaces 41B includes a sloped surface located at the first portion 41C, and an upright surface located at the second portion 41D. Moreover, the overall shape of the first magnetic collecting unit 41 is not limited to being the shape shown in FIG. 3. For example, the overall shape of the first magnetic collecting unit 41 can also be a polygonal prism shape such as a rectangular shape. For example, by forming both of the first support portion 45 and the second support portion 45 as rectangular shapes, the overall shape of the first magnetic collecting unit 41 can be set as a rectangular shape.

Next, the configuration of the first magnetic collecting unit 41 is described below.

As shown in FIG. 1, in the thickness direction of the substrate 30, the first magnetic collecting unit 41 is disposed on a position overlapping the sensor unit 21of the magnetic detection element 20. More particularly, preferably, at least portion of an end portion of the magnetic side surface 41B of the first magnetic collecting unit 41 on a side of the magnetic detection element 20 overlaps the sensor unit 41 of the magnetic detection element 20. In this case, a magnetic flux collected by the magnetic collecting side surface 41B of the first magnetic collecting unit 41 and induced to the sensor unit 21 of the magnetic detection element 20 can be enhanced. Thus, preferably, an entirety of an end portion of the magnetic side surface 41B of the first magnetic collecting unit 41 on a side of the magnetic detection element 20 is configured to overlap the sensor unit 41 of the magnetic detection element 20. Moreover, an end portion of the magnetic collecting side surface 41B on a side of the substrate 30 can be configured to partially or entirely overlap the sensor unit 21 of the magnetic detection unit 20 in the thickness direction of the substrate 30, or can be configured to not overlap the sensor unit 21 at all.

Moreover, as shown in FIG. 1, in the thickness direction of the substrate 30, the first magnetic collecting unit 41 can be separated from the sensor unit 21 of the magnetic detection element 20 or be in contact with the sensor unit 21. When the first magnetic collecting unit 41 is separated from the sensor unit 21, short-circuity between the first magnetic collecting unit 41 and the sensor unit 41 can be inhibited. A separation length L5 between the first magnetic collecting unit 41 and the sensor unit 21 is, for example, between about 0.1 μm and about 100 μm. When the first magnetic collecting unit 41 is separated from the sensor unit 21, preferably, the insulating layer 50 is interposed between the first magnetic collecting unit 41 and the sensor unit 21.

### [Second Magnetic Collecting Unit]

As shown in FIG. 1, the second magnetic collecting unit 42 is a portion have a tablet shape extending on the bottom surface 32 of the recess 31. The second magnetic collecting unit 42 is made of a magnetic material. The magnetic material forming the second magnetic collecting unit 42 is, for example, ferrite, Fe and Ni. In one example, the second magnetic collecting unit 42 is made of a same material as the magnetic film 44, and is formed to be continuous from the magnetic film 44. A thickness of the second magnetic collecting unit 42 is, for example, between about 0.1 μm and about 50 μm.

The second magnetic collecting unit 42 protrudes laterally from an end portion of the first magnetic collecting unit 41 on a side of the substrate 30. The so-called “protruding laterally” means protruding in a direction (along a direction of the X-Y plane) perpendicular to the thickness direction (the Z direction) of the substrate 30. The second magnetic collecting unit 42 can protrude in a specific direction or multiple specific directions perpendicular to the thickness direction of the substrate 30, or can protrude in all of the directions perpendicular to the thickness direction of the substrate 30.

The second magnetic collecting unit 41 has a base end portion 42A continuous with the first magnetic collecting unit 41, and a front end portion 42B located on an outer periphery of the second magnetic collecting unit 42 in the plan view. Preferably, at least a portion of the front end portion 42B of the second magnetic collecting unit 42 is exposed from the sensor unit 21 of the magnetic detection element 20, and more preferably, the front end portion 42B is entirely exposed from the sensor unit 21 of the magnetic detection element 20. Moreover, the second magnetic collecting unit 42 can also have a shape in which the front end portion 42B is not exposed from the sensor unit 21 of the magnetic detection element 20 in the plan view.

FIG. 3 shows a perspective diagram of the magnetic collector 40 to represent an example of the shape of the magnetic collector 40. A shape of the second magnetic collecting unit 42 shown in FIG. 3 is specifically described below. The second magnetic collecting unit 42 has a rectangular profile in the plan view. The second magnetic collecting unit 42 has four sides 42C individually located on four sides of a rectangle and parallel to the X direction or the Y direction. Each of the four sides 42C is the front end portion 42B of the second magnetic collecting unit 42.

A length L6 from the base end portion 42A to the side 42C in the second magnetic collecting unit 42 can be the same as that of another, or can be different for each of the four sides 42C. At least one side 42C of the four sides 42C is preferably formed such that the length L6 from the base end portion 42A to the side 42C is 0.1 μm or more. When the length L6 is extended, by extensively forming the second magnetic collecting unit 42, the magnetic flex within a broader range can be collected. Moreover, a magnetic collection effect produced by the extensively formed second magnetic collecting unit 42 is rather limited. Thus, from the perspective of inhibiting overly enlarging the magnetic collector 40, the length L6 is limited to be 100 μm or less. Moreover, the overall shape of the second magnetic collecting unit 42 is not limited to being the shape shown in FIG. 3. For example, the bottom surface 42 of the recess 31 in the plan view can also be have other shapes such as a square, a polygon or a circle.

### (Insulating Layer)

The insulating layer 50 can be made of an insulative resin material such as epoxy, or a material containing at least one of silicon dioxide (SiO₂), silicon nitride (SiN), silicon oxynitride (SiON), aluminum oxide (Al₂O₃), aluminum nitride (AlN) and aluminum oxynitride (AlON).

As shown in FIG. 1, the insulating layer 50 is formed on the substrate 30 to cover the opposing surface 30A of the substrate 30 and the magnetic collector 40. An entire surface of the magnetic collector 40, that is, entire surfaces of the magnetic collecting opposing surface 41A and the magnetic collecting side surface 41B of the first magnetic collecting unit 41 as well as the second magnetic collecting unit 42, is covered by the insulating layer 50. Moreover, the recess 31 of the substrate 30 is buried by the insulating layer 50. The insulating layer 50 has an upper surface 50A located opposite to the substrate 30. The upper surface 50A is a surface parallel to the opposing surface 30A of the substrate 30. The magnetic detection element 20 is disposed on the upper surface 50A of the insulating layer 50.

(Manufacturing Method of Magnetic Detection Device).

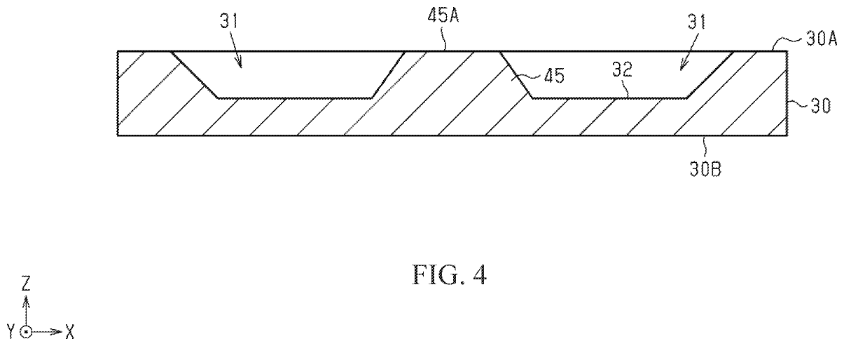

FIG. 4 to FIG. 6 show brief section diagram of exemplary manufacturing steps of the magnetic detection device 10. Moreover, for better understanding, in FIG. 4 to FIG. 6, the constituting elements the same as the constituting elements in FIG. 1 are denoted by the same numerals or symbols.

As shown in FIG. 4, first of all, with respect to the opposing surface 30A of the substrate 30 which is a Si substrate in a tablet shape, a recess 31 having a protruding portion, that is, a first supporting portion 45, is formed at a center. The recess 31 and the first support portion 45 can be formed by selectively removing a portion of the substrate 30 by means of etching.

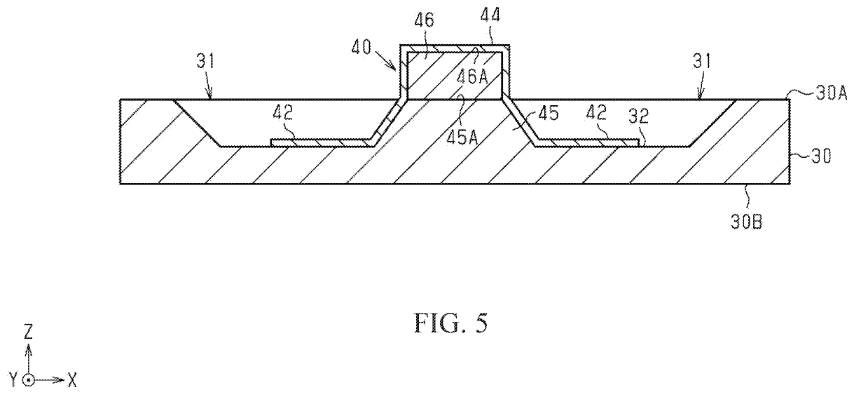

Next, as shown in FIG. 5, the second support portion 46 made of Cu is formed on the upper surface 45A of the first support portion 45. Then, the magnetic film 44 covering the first support portion 45, the second support portion 46 and a portion of the bottom surface 32 of the recess 31, and the second magnetic collecting unit 42, are formed. The magnetic film 44 and the second magnetic collecting unit 24 can be formed by means of, for example, electrolytic plating or electroless plating. Accordingly, the magnetic collector 40 is formed on the substrate 30.

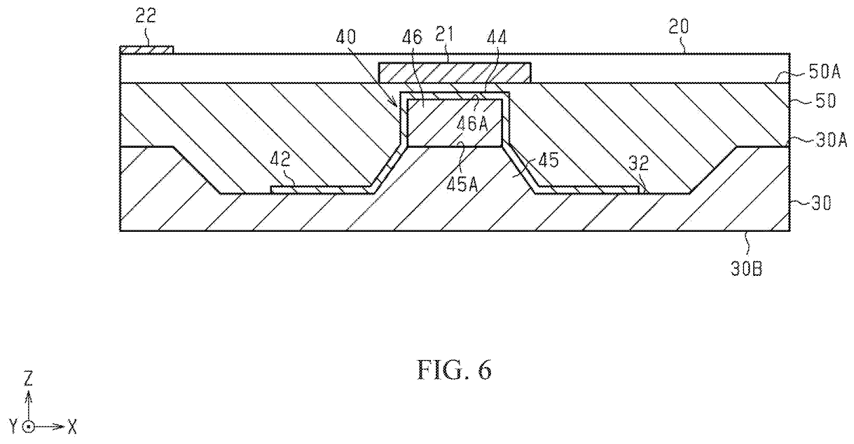

Next, as shown in FIG. 6, the insulating layer 50 is formed on the substrate 30. In one example, the insulating layer 50 is an insulating resin layer formed by means of plastic molding. Then, the magnetic detection element 20 is mounted on the insulating layer 50.

### (Effects)

Next, effects of the magnetic detection device 10 of the first embodiment are described.

The magnetic detection device 10 includes the magnetic collector 40, which is disposed between the magnetic detection element 20 and the substrate 30 and induces a magnetic flux to the magnetic detection element 20. The magnetic collector 40 includes a first magnetic collecting unit 41 that erects from the substrate 30 toward the magnetic detection element 20. With the magnetic collector 40 disposed between the magnetic detection element 20 and the substrate 30, the magnetic flux passing around the magnetic collector 40 is induced along the first magnetic collecting unit 41 of the magnetic collector 40 to the magnetic detection element 20. Accordingly, as a magnetic flux density of magnetic detection element 20 is increased, the detection accuracy of a magnetic field by the magnetic detection element 20 is also improved.

Moreover, the magnetic collector 40 includes the second magnetic collecting unit 42 more protruded laterally than the first magnetic collecting unit 41. Accordingly, in addition to the magnetic flux passing through around the first magnetic collecting unit 41, the magnetic flux passing through the second magnetic collecting unit 42 is also induced to the magnetic detection element 20 via the second magnetic collecting unit 42 and the first magnetic collecting unit 41. Thus, as a magnetic flux density of magnetic detection element 20 is further increased, the detection accuracy of a magnetic field by the magnetic detection element 20 is also improved.

Moreover, the recess 31 recessed from the opposing surface 30A in a direction opposite to the magnetic detection element 20 is formed on the substrate 30. At least a portion of the magnetic collector 40 is disposed within the recess 31 of the substrate 30. More specifically, the first magnetic collecting unit 41 of the magnetic collector 40 is formed to erect from the bottom surface 32 of the recess 31 toward the magnetic detection element 20. Thus, the first magnetic collecting unit 41 enters the substrate 30 by an amount of the length L1 from the opposing surface 30A of the substrate 30 to the bottom surface 32 of the recess 31.

Accordingly, the height size (the length L4) of the first magnetic collecting unit 41 can be ensured to be constant, and the protruding length of the first magnetic collecting unit 41 from the opposing surface 30A of the substrate 30, that is, the length from the opposing surface 30A to the magnetic collecting opposing surface 41A of the first magnetic collecting unit 41, can be reduced. In this case, the magnetic detection element 20 disposed on the first magnetic collecting unit 41 can be disposed to be closer to the opposing surface 30A of the substrate 30. Thus, an increase in the height size of the magnetic detection device 10 due to the magnetic collector 40 provided can be inhibited.

### (Effects)

The magnetic detection device 10 according to the first embodiment achieves the following effects.

### (1-1)

The magnetic detection device 10 includes the magnetic detection element 20, the substrate 30 having the opposing surface 30A facing the magnetic detection element 20, and the magnetic collector 40 disposed between the magnetic detection element 20 and the substrate 30 and configured to induce a magnetic flux to the magnetic detection element 20. The substrate 30 includes the recess 31 recessed from the opposing surface 30A in a direction opposite to the magnetic detection element 20. At least a portion of the magnetic collector 40 is disposed within the recess 31. The magnetic collector 40 includes the first magnetic collecting unit 41 that erects from a bottom surface 32 of the recess 31 toward the magnetic detection element 20.

According to the configuration above, the detection accuracy of a magnetic field by the magnetic detection element 20 is also improved with the magnetic collector 40 disposed between the magnetic detection element 20 and the substrate 30. Moreover, by disposing at least one portion of the magnetic collector 40 within the recess 31 of the substrate 30, the magnetic detection element 20 can be disposed to be closer to the opposing surface 30A of the substrate 30. Thus, an increase in the height size of the magnetic detection device 10 due to the magnetic collector 40 provided can be inhibited.

### (1-2)

In the thickness direction of the substrate 30, the end portion (the magnetic collecting opposing surface 41A) of the first magnetic collecting unit 41 is located closer to the magnetic detection element 20 than the opposing surface 30A of the substrate 30. According to the configuration above, the length L4 of the first magnetic collecting unit 41 can be increased. As the length L4 of the first magnetic collecting unit 41 is increased, an effect of inducing the magnetic flux in the first magnetic collecting unit 41 to the magnetic detection element 20 is enhanced.

### (1-3)

The first magnetic collecting unit 41 includes a support portion 43 which is cylindrical and erects from the bottom surface 32 of the recess 31 toward the magnetic detection element 20, and a magnetic film 44 coated on a surface of the support portion 43. According to the configuration above, only the first magnetic collecting unit 41 is made of a magnetic material. Thus, the magnetic flux passing through the first magnetic collecting unit 41 is concentrated on the surface of the first magnetic collecting unit 41. Accordingly, the effect of inducing the magnetic flux in the first magnetic collecting unit 41 to the magnetic detection element 20 is further enhanced.

### (1-4)

The side surface of the first magnetic collecting unit 41, that is, at least a portion of the magnetic collecting side surface 41B, is an upright surface perpendicular to the opposing surface 30A of the substrate 30. The effect of inducing the magnetic flux of the first magnetic collecting unit 41 to the magnetic detection element 20 is increased as the magnetic collecting side surface 41B of the first magnetic collecting unit 41 approaches parallel to a direction from the substrate 30 to the magnetic detection element 20. Accordingly, according to the configuration above, the effect of inducing the magnetic flux in the first magnetic collecting unit 41 to the magnetic detection element 20 is enhanced.

### (1-5)

The support 43 includes the support sloped surface (the first support portion 45) having a cross-sectional area gradually decreasing from the bottom surface 32 of the recess 31 toward the magnetic detection element 20, and the support upright portion (the second support portion 46) having a constant cross-sectional area from the upper end of the support sloped portion toward the magnetic detection element 20. The magnetic film 44 is coated on a surface of the support sloped portion and a surface of the support upright portion.

According to the configuration above, a portion in the support portion 43 close to the magnetic detection element 20 is formed by the support upright portion. Since all of the side surfaces of the support upright portion are the upright surfaces, the effect of (1-4) becomes even greater.

### (1-6)

The support sloped portion (the first support portion 45) is made of a same material as the substrate 30. The support upright portion (the second support portion 46) is made of a different material from the substrate 30. According to the configuration above, the support sloped portion and the support upright portion having different shapes from each other can be easily formed. Moreover, by modifying a height size of the support upright portion, the length L4 of the first magnetic collecting unit 41 can be easily adjusted. More particularly, the end portion of the first magnetic collecting unit 41 on a side of the magnetic detection element 20 can be easily made to be located closer to the magnetic detection element 20 than the opposing surface 30A of the substrate 30.

### (1-7)

In the thickness direction of the substrate 30, the length L2 of the support sloped portion (the first support portion 45) is greater than a length L3 of the support upright portion (the second support portion 46). According to the configuration above, a process for forming the support sloped portion and the support upright portion can be easily performed.

### (1-8)

In the thickness direction of the substrate 30, the length L2 of the support sloped portion (the first support portion 45) is less than a length L3 of the support upright portion (the second support portion 46). According to the configuration above, the length of the support upright portion is increased. Thus, the effect of (1-4) is made even greater.

### (1-9)

The first magnetic collecting unit 41 has a rectangular shape with the thickness direction of the substrate 30 as a height direction. According to the configuration above, all of the magnetic collecting side surfaces 41B of the first magnetic collecting unit 41 are the upright surfaces, so that the effect of (1-4) becomes even greater.

### (1-10)

The magnetic collector 40 includes the second magnetic collecting unit 42 more protruded laterally than the first magnetic collecting unit 41 in the plan view. The magnetic collector 40 induces a magnetic flux passing through the second magnetic collecting unit 42 to the magnetic detection element 20 via the first magnetic collecting unit 41. According to the configuration above, the magnetic flux passing through around the magnetic detection element 20 is collected by the second magnetic collecting unit 42, and is inducted to the magnetic detection element 20 via the first magnetic collecting unit 41. Accordingly, the detection accuracy of a magnetic field by the magnetic detection element 20 is improved.

### (1-11)

The second magnetic collecting unit 41 has a base end portion 42A continuous with the first magnetic collecting unit 41, and a front end portion 42B located on an outer periphery of the second magnetic collecting unit 42 in the plan view. At least a portion of the front end portion 42B of the second magnetic collecting unit 42 is exposed from the sensor unit 21 of the magnetic detection element 20 in the plan view. Thus, the effect of (1-10) is made even greater.

### <Second Embodiment>

The configuration of the first magnetic collecting unit 41 of the magnetic collector 40 of a magnetic detection device 110 of the second embodiment is different from that of the first embodiment. The remaining configuration details are the same as those of the first embodiment. In the description below, associated details of the constituting elements common with those of the first embodiment are omitted for brevity, and only details of constituting elements different from those of the first embodiment are described.

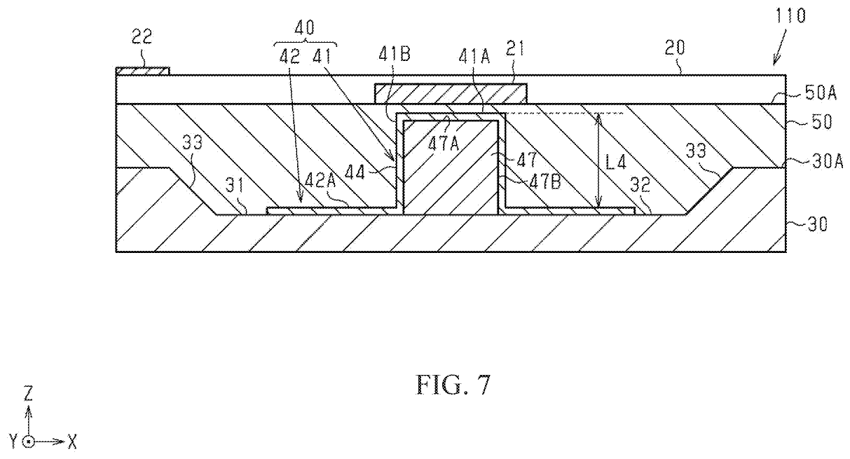

FIG. 7 shows a brief section diagram of the magnetic detection device 110. Only the magnetic detection device 110 is depicted in FIG. 7. As shown in FIG. 7, the first magnetic collecting unit 41 includes a support portion 47 which is cylindrical and erects from the bottom surface 32 of the recess 31 toward the magnetic detection element 20, and the magnetic film 44 coated on a surface of the support portion 47.

The bottom surface 32 of the recess 31 of the second embodiment is formed to be flat in overall. The support portion 47 is a component different from the substrate 30, and is disposed on the bottom surface 32 of the recess 31. The support portion 47 is made of a different material from the substrate 30. The material forming the support portion 47 is, for example, a non-magnetic material such as Cu. Moreover, the material forming the support portion 47 can also be a magnetic material.

The support portion 47 is disposed at a center of the bottom surface 32 of the recess 31 in the plan view, and is separated from the side surface 33 of the recess 31. The support portion 47 has an upper surface 47A on an end portion of the support portion 47 located on a side of the magnetic detection element 20, and a side surface 47B extending from an end portion of the support portion 47 on a side of the bottom surface 32 of the recess 31 toward the upper surface 47A. The upper surface 47A of the support portion 47 is a surface parallel to the opposing surface 30A of the substrate 30. In the thickness direction of the substrate 30, the upper surface 47A of the support portion 47 is located closer to the magnetic detection element 20 than the opposing surface 30A of the substrate 30. That is to say, a protruding height of the support portion 47 is greater than the depth (the length L1) of the recess 31. Moreover, the position of the upper surface 47A of the support portion 47 can also be the same as that of the opposing surface 30A.

The side surface 47B of the support portion 47 is a vertical surface perpendicular to the bottom surface 32 of the recess 31. Moreover, the side surface 47B of the support portion 47 can also be a sloped surface sloped relative to the bottom surface 32 of the recess 31. In addition, the support portion 47 can have the side surface 47B which is the sloped surface, and the side surface 47B which is the vertical surface.

The support portion 47 has a profile of, for example, a polygonal prism shape such as a square prism shape having a constant cross-sectional area from the bottom surface 32 of the recess 31 toward the magnetic detection element 20. Moreover, the support portion 47 can also have a profile of, for example, a polygonal pyramid shape such as a square pyramid shape having a cross-sectional area gradually decreasing from the bottom surface 32 of the recess 31 toward the magnetic detection element 20.

For the first magnetic collecting unit 41 of the second embodiment, regardless of the position of the opposing surface 30A of the substrate 30, the length L4 of the first magnetic collecting unit 41 can be adjusted by modifying the height size of the support portion 47. Thus, the magnetic collecting opposing surface 41A of the first magnetic collecting unit 41 can be made to be located closer to the magnetic detection element 20 than the opposing surface 30A of the substrate 30, hence easily increasing the length L4 of the first magnetic collecting unit 41.

### (Effects)

The magnetic detection device 110 according to the second embodiment achieves the following effects.

### (2-1)

The first magnetic collecting unit 41 includes a support portion 47 which is cylindrical and erects from the bottom surface 32 of the recess 31 toward the magnetic detection element 20, and a magnetic film 44 coated on a surface of the support portion 47. The support portion 47 is made of a different material from the substrate 30. According to the configuration above, by modifying the height size of the support portion 47, the length L4 of the first magnetic collecting unit 41 can be easily adjusted.

### <Variation Examples>

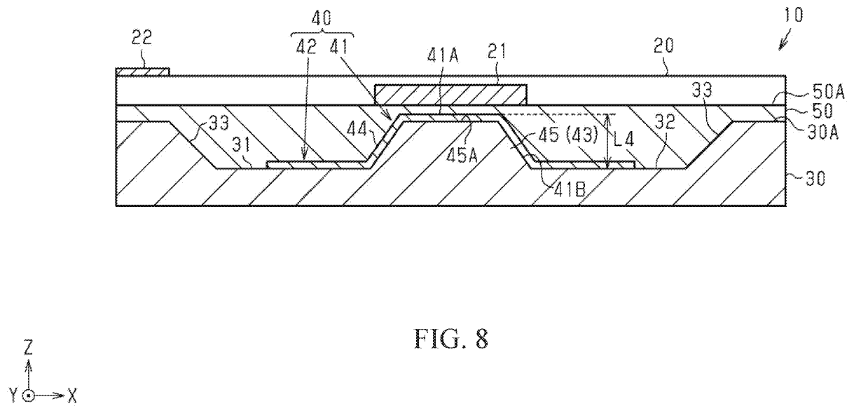

The embodiments can be modified as the following variation examples. Given that no technical contradiction is resulted, the following variation examples may be used in combination. Moreover, In the variation examples below, parts that are common with the embodiment describe above are denoted by the same numerals and symbols, and the related description is omitted.
As shown in FIG. 8, for the first magnetic collecting unit 41 related to the first embodiment, the support portion 43 can also be configured to omit the second support portion 46. Moreover, in this case, in the thickness direction of the substrate 30, the end portion of the first magnetic collecting unit 41 on a side of the magnetic detection element 20, that is, the magnetic collecting opposing surface 41A, can also be located at a same position as the opposing surface 30A of the substrate 30, or be located closer to the bottom surface 32 of the recess than the opposing surface 30A.
For the first magnetic collecting unit 41 related to the second embodiment, the support portion 47 can also be omitted such that a hollow-shaped first magnetic collecting unit 41 is formed. In this case, the magnetic film 44 is formed by a rigid magnetic material capable of maintaining a shape.
The first magnetic collecting unit 41 related to the second embodiment can also be modified and configured to include the support portion 47 and the magnetic film 44, and the first can also be entirely made of a solid magnet.
The first magnetic collector 40 of the various embodiments can also be configured to omit the second magnetic collecting unit 42.

The terms such as “on” used in the present disclosure also includes meanings of both “over” and “above”, unless otherwise specified in the context. Thus, an expression such as “a configuration A formed on a configuration B” means that, in some embodiments, the configuration A can be in contact with the configuration B and be directly disposed on the configuration B, while in other embodiments, the configuration A can be disposed over the configuration B without coming into contact with the configuration B. That is to say, the expression “on” does not eliminate a structure having another component formed between the configuration A and configuration B.

The Z-axis direction used in the present disclosure is not necessarily a vertical direction, and is not necessarily completely consistent with the vertical direction. Thus, various structures associated with the present disclosure do not limit “up/top” and “down/bottom” of the Z direction given in the description to be “up” and “down” of the vertical direction. For example, the X direction can be the vertical direction, or the Y direction can be the vertical direction.

The terms “first”, “second” and “third” of the present disclosure are for distinguishing target objects, and are not intended for sorting an order of the target objects.

### <Notes>

The technical concepts encompassed by the present disclosure are recorded in the description below. Moreover, to help better understand rather than intended as limitations, the constituting elements described in the notes are given with the same reference numerals or symbols of the corresponding constituting elements in the embodiments. The numerals or symbols are used as examples for understanding purposes, and the constituting elements described in the notes are not to be construed as limited to the constituting elements indicated by the numerals or symbols.

### [Note 1]

A magnetic detection device (10, 110), comprising:
a magnetic detection element (20);
a substrate (30), having an opposing surface (30A) facing the magnetic detection element (20); and
a magnetic collector (40), disposed between the magnetic detection element (20) and the substrate (30) and configured to induce a magnetic flux to the magnetic detection element (20), wherein
the substrate (30) has a recess (31) recessed from the opposing surface (30A) in a direction opposite to the magnetic detection element (20), at least a portion of the magnetic collector (40) is disposed within the recess (31), and the magnetic collector (40) includes a first magnetic collecting unit (41) that erects from a bottom surface (32) of the recess (31) toward the magnetic detection element (20).

### [Note 2]

The magnetic detection device (10, 110) according to note 1, wherein in a thickness direction of the substrate (30), an end portion of the first magnetic collecting unit (41) on a side of the magnetic detection element (20) is located at the same position as the opposing surface (30A) of the substrate (30), or closer to the magnetic detection element (20) than the opposing surface (30A).

### [Note 3]

The magnetic detection device (10, 110) according to note 1 or note 2, wherein the first magnetic collecting unit (41) includes:
a support portion (43, 47), which is cylindrical and erects from the bottom surface (32) of the recess (31) toward the magnetic detection element (20); and
a magnetic film (44), coated on a surface of the support portion (43, 47).

### [Note 4]

The magnetic detection device (10) according to note 3, wherein the support portion (43) includes:
a support sloped portion (a first support portion 45), having a cross-sectional area gradually decreasing from the bottom surface (32) of the recess (31) toward the magnetic detection element (20); and
a support upright portion (a second support potion 46), having a constant cross-sectional area from an upper end (an upper surface 45A) of the support sloped portion (the first support portion 45) toward the magnetic detection element (20), wherein
the magnetic film (44) is coated on a surface of the support sloped portion (the first support portion) and a surface of the support upright portion (the second support portion 46).

### [Note 5]

The magnetic detection device (10) according to note 4, wherein the support sloped portion (the first support portion 45) is made of a same material as the substrate (30), and the support upright portion (the second support portion 46) is made of a material different from the substrate (30).

### [Note 6]

The magnetic detection device (10) according to note 5, wherein in a thickness direction of the substrate (30), a length (L2) of the support sloped portion (the first support portion 45) is greater than a length (L3) of the support upright portion (the second support portion 46).

### [Note 7]

The magnetic detection device (10) according to note 5, wherein in a thickness direction of the substrate (30), a length (L2) of the support sloped portion (the first support portion 45) is less than a length (L3) of the support upright portion (the second support portion 46).

### [Note 8]

The magnetic detection device (10, 110) according to any one of notes 4 to 7, wherein at least a portion of the support upright portion (the second support portion 46) is located closer to the magnetic detection element (20) than the opposing surface (30A) of the substrate (30).

### [Note 9]

The magnetic detection device (10, 110) according to any one of notes 1 to 8, wherein at least a portion of a side surface (a magnetic collecting side 41B) of the first magnetic collecting unit (41) is perpendicular to the opposing surface (30A) of the substrate (30).

### [Note 10]

The magnetic detection device (10, 110) according to note 9, wherein the first magnetic collecting unit (41) has a rectangular shape with a thickness direction of the substrate (30) as a height direction.

### [Note 11]

The magnetic detection device (10, 110) according to any one of notes 1 to 10, wherein the magnetic collector (40) includes a second magnetic collecting unit (42) protruded more laterally than the first magnetic collecting unit (41) in a plan view from a thickness direction of the substrate (30), and the magnetic collector (40) is configured to induce a magnetic flux passing through the second magnetic collecting unit (42) to the magnetic detection element (20) via the first magnetic collecting unit (41).

### [Note 12]

The magnetic detection device (10, 110) according to note 10, wherein the second magnetic collecting unit (42) has a rectangular profile in the plan view.

### [Note 13]

The magnetic detection device (10, 10) according to any one of notes 1 to 12, wherein the substrate (30) is a silicon substrate.

1. A magnetic detection device, comprising:
a magnetic detection element;
a substrate, having an opposing surface facing the magnetic detection element; and
a magnetic collector, disposed between the magnetic detection element and the substrate and configured to induce a magnetic flux to the magnetic detection element, wherein
the substrate has a recess recessed from the opposing surface in a direction opposite to the magnetic detection element,
at least a portion of the magnetic collector is disposed within the recess, and
the magnetic collector includes a first magnetic collecting unit that stands up from a bottom surface of the recess toward the magnetic detection element.

2. The magnetic detection device of claim 1, wherein in a thickness direction of the substrate, an end portion of the first magnetic collecting unit on a side of the magnetic detection element is located
at same position as the opposing surface of the substrate, or
closer to the magnetic detection element than the opposing surface.

3. The magnetic detection device of claim 1, wherein the first magnetic collecting unit includes:
a support portion, which is cylindrical and stands up from the bottom surface of the recess toward the magnetic detection element; and
a magnetic film, coated on a surface of the support portion.

4. The magnetic detection device of claim 3, wherein the support portion includes:
a support sloped portion, having a cross-sectional area gradually decreasing from the bottom of the recess toward the magnetic detection element; and
a support upright portion, having a constant cross-sectional area from an upper end of the support sloped portion toward the magnetic detection element, wherein
the magnetic film is coated on a surface of the support sloped portion and a surface of the support upright portion.

5. The magnetic detection device of claim 4, wherein
the support sloped portion is made of same material as the substrate, and
the support upright portion is made of a material different from the substrate.

6. The magnetic detection device of claim 5, wherein in a thickness direction of the substrate, a length of the support sloped portion is greater than a length of the support upright portion.

7. The magnetic detection device of claim 5, wherein in a thickness direction of the substrate, a length of the support sloped portion is less than a length of the support upright portion.

8. The magnetic detection device of claim 4, wherein at least a portion of the support upright portion is located closer to the magnetic detection element than the opposing surface of the substrate.

9. The magnetic detection device of claim 1, wherein at least a portion of a side surface of the first magnetic collecting unit is perpendicular to the opposing surface of the substrate.

10. The magnetic detection device of claim 9, wherein the first magnetic collecting unit has a rectangular shape with a thickness direction of the substrate as a height direction.

11. The magnetic detection device of claim 1, wherein
the magnetic collector includes a second magnetic collecting unit protruded more laterally than the first magnetic collecting unit in a plan view from a thickness direction of the substrate, and
the magnetic collector is configured to induce a magnetic flux passing through the second magnetic collecting unit to the magnetic detection element via the first magnetic collecting unit.

12. The magnetic detection device of claim 11, wherein the second magnetic collecting unit has a rectangular profile in the plan view.

13. The magnetic detection device of claim 1, wherein the substrate is a silicon substrate.
